(19) United States
(12) Patent Application Publication
(10) Pub. No.: US 2014/0203796 A1
(43) Pub. Date: Jul. 24, 2014

(54) NANOELECTROMECHANICAL RESONATORS

(71) Applicant: Purdue Research Foundation, West Lafayette, IN (US)

(72) Inventors: Saeed Mohammadi, Zionsville, IN (US); Hossein Pajouhi, West Lafayette, IN (US); Jeffrey Frederick Rhoads, West Lafayette, IN (US); Lin Yu, San Jose, CA (US)

(73) Assignee: Purdue Research Foundation, West Lafayette, IN (US)

(21) Appl. No.: 13/968,836

(22) Filed: Aug. 16, 2013

Related U.S. Application Data
(60) Provisional application No. 61/684,259, filed on Aug. 17, 2012.

(51) Int. Cl. H01L 27/12; G01R 19/00; H01L 29/02

(52) U.S. Cl. CPC H01L 27/1203; H01L 29/02; G01R 19/0015
USPC 324/76.11; 257/351; 257/632

(57) ABSTRACT

A silicon device, e.g., a nanoelectromechanical resonator, has a silicon substrate; an oxide layer having a trench therein; a silicon device layer over the oxide layer; and a nanowire disposed at least partly over the trench. Substantially no oxide or polysilicon is over the nanowire in the trench. A polyimide layer over the silicon device layer includes an opening over the trench. A silicon device can include silicon-on-insulator layers and at least one complementary metal-oxide semiconductor transistor in addition to a nanowire substantially suspended over a trench. A system for measurement of a nanoresonator includes an AC source in series with the nanoresonator to provide an electrical signal thereto at a selected first frequency. Electrode(s) adjacent to and spaced apart from the nanoresonator are driven by voltage source. A detector detects a current through the nanoresonator.

### CROSS-REFERENCE TO RELATED APPLICATIONS

This application is a nonprovisional application of U.S. Patent Application Ser. No. 61/684,259, filed Aug. 17, 2012 and entitled “Nanoelectromechanical Resonators,” the entirety of which is incorporated herein by reference.

### STATEMENT OF FEDERALLY SPONSORED RESEARCH OR DEVELOPMENT

This invention was made with government support under grant number 0826276 awarded by the National Science Foundation. The government has certain rights in the invention.

### TECHNICAL FIELD

The present disclosure generally relates to micro- and nano-electromechanical systems, and in particular to resonators in such systems.

### BACKGROUND

Nanoelectromechanical systems (NEMS) are eliciting great interest in various electronic fields. In one such field NEMS have received interests because these devices allow access to microwave frequencies and nanosecond response times, amongst other pertinent metrics. These properties permit NEMS to be useful in analog and radio frequency (RF) signal processing, nanomechanical electrometry, and chemical and biological sensing. For example, nanoresonators can be used in bandpass filters and scanning probe microscopes. The resonant frequency change of a nanoresonator upon the addition of mass or a change in stiffness can be used to signal that a desired analyte has been brought into contact or proximity with the nanoresonator. Radio-frequency (RF) signals can also be applied to nanoresonators, which will pass only signals in the resonant band. Nanoresonators can also be used in accelerometers.

NEMS fabrication techniques for post-complementary metal oxide semiconductor (CMOS) processes are needed to allow NEMS to be economically feasible. To date, most NEMS resonators have been fabricated using a bottom-up carbon nanotube (CNT) or nanowire (NW) synthesis technique, followed by low-temperature top-down microfabrication. While this approach can be adopted for post-CMOS device fabrication, it is quite susceptible to processing, material, and geometric variability, which leads to irreproducible near-resonant response characteristics and, ultimately, prohibits predictive device design.

Resonant NEMS devices fabricated using only a top-down approach have also been reported. However, these devices generally cannot be fabricated and integrated as a single-chip solution in mass sensing or signal processing applications, as technologies that are not based on Si resonators are generally incompatible with CMOS processing, and devices which rely on piezoelectric, magnetomotive, or optical transduction typically require additional hardware to fully characterize their near-resonant response.

There is therefore a need for a CMOS compatible processing technique to permit effectively and economically manufacturing NEMS devices, and in particular NEMS-based resonators, mass sensing devices, and signal processing components. There is also a need for such devices fabricated on-chip with CMOS electronics.

### BRIEF DESCRIPTION

According to various aspects described in the present disclosure, a dual-gate, nonlinear nanoelectromechanical resonator fabricated using a silicon-on-insulator (SOI) process flow is provided. The resonator is configured to be nonlinear and tunable. The resonator can be further configured to have a Duffing-like frequency response characteristic, when excited above the noise floor, and thus offers a hysteresis with respect to the excitation frequency over a finite bandwidth.

According to one aspect, there is provided a device comprising:
a) a silicon substrate, an oxide layer disposed over the silicon substrate and including a trench, and a silicon device layer disposed over the oxide layer;
b) at least one complementary metal-oxide-semiconductor (CMOS) transistor;
c) a nanowire substantially suspended over the trench and electrically connected at each end to a respective contact; and
d) two gate electrodes, each spaced apart from the nanowire and operatively arranged to develop a respective capacitance with the nanowire, wherein the two gate electrodes lie along different axes with respect to the nanowire;
e) so that the nanowire can be excited to vibrate in an in-plane mode or an out-of-plane mode by controlling a current through the contacts and a respective bias of each of the two gate electrodes.

According to another aspect, there is provided a silicon device comprising:
a) a silicon substrate;
b) an oxide layer disposed over the silicon substrate, the oxide layer having a trench therein;
c) a silicon device layer disposed over the oxide layer, the silicon device layer including a nanowire disposed at least partly over the trench, wherein substantially no oxide or polysilicon is disposed over the nanowire within a lateral extent of the trench; and
d) a polyimide layer disposed over the silicon device layer, the polyimide layer including an opening substantially arranged over the trench.

According to another aspect, there is provided a system for measurement of a nanoresonator, the system comprising:
a) an AC source in series with the nanoresonator, the AC source adapted to provide an electrical signal to the nanoresonator at a selected first frequency;
b) one or more electrode(s), each arranged adjacent to and spaced apart from the nanoresonator, and a voltage source adapted to apply respective selected voltage(s) to the electrode(s); and
c) a detector adapted to detect a current through the nanoresonator.

In various aspects, a dual-gate, nonlinear nanoelectromechanical resonator based on a silicon-on-insulator (SOI) process flow is disclosed. The resonator is configured to be nonlinear and tunable. The resonator is further configured to have a Duffing-like frequency response characteristic, when excited above the noise floor, and thus offers a hysteresis with respect to the excitation frequency over a finite bandwidth.

Various aspects provide nanoscale devices that can be fabricated using an entirely top-down process without significant postprocessing. This permits the manufacturing of such devices in volume.

This brief description is intended only to provide a brief overview of subject matter disclosed herein according to one or more illustrative embodiments, and does not serve as a guide to interpreting the claims or to define or limit the scope of the invention. This brief description is provided to introduce an illustrative selection of concepts in a simplified form that are further described below in the detailed description. This brief description is not intended to identify key features or essential features of any claimed subject matter, nor is it intended to be used as an aid in determining the scope of any claimed subject matter. The claimed subject matter is not limited to implementations that solve any or all disadvantages noted in the background.

### BRIEF DESCRIPTION OF DRAWINGS

The above and other objects, features, and advantages of the present invention will become more apparent when taken in conjunction with the following description and drawings wherein identical reference numerals have been used, where possible, to designate identical features that are common to the figures, and wherein:

FIG. 1(a) is a rendering, and FIG. 1(b) a representation of a micrograph, showing representative silicon-on-insulator nanoelectromechanical system (SOI-NEMS) devices, according to various aspects.

FIGS. 1(c) and 1(d) are scanning electron microscope images of a nanowire according to various aspects.

FIG. 1(e) is a graph of linear resonant frequencies of six nanoresonators according to various aspects.

FIG. 1(f) is a schematic of a nanoresonator and a system for measuring characteristics of nanoresonators according to various aspects.

FIG. 1(g) is a graph of measured linear resonant frequencies of nine nanoresonator devices with different geometries and a comparison to a theoretical prediction.

FIG. 2 is an atomic force microscopic image of an exemplary suspended silicon nanowire resonator fabricated according to various aspects.

FIG. 3 shows graphs of experimental frequency responses obtained from a dual-gate nanoresonator according to various aspects.

FIG. 4 illustrates measured resonant response of a representative dual-gate nanoresonator at different side-gate bias voltages with a fixed bias on the back gate according to various aspects.

FIG. 5 illustrates measured resonant response of a representative dual-gate nanoresonator at different side-gate bias voltages with a fixed bias on the back gate.

FIG. 6 illustrates measured near-resonant, planar response of a representative silicon nanoresonator obtained by exciting the system with various AC source-drain voltages (V_{ds}) while sweeping the excitation frequency (a) up and down.

FIG. 7 illustrates measured near-resonant, non-planar response of a representative silicon nanoresonator obtained by exciting the system with various AC source-drain voltages (V_{ds}) while sweeping the excitation frequency (co) up and down.

FIG. 8 shows experimentally-determined bifurcation diagrams.

FIG. 9 shows experimentally-determined bifurcation diagrams.

FIGS. 10(a)-10(d) are cross-sections of an exemplary wafer at various stages of the fabrication of a nanoresonator according to various aspects.

FIG. 11 is a representation of a micrograph of a portion of a nanoresonator fabricated using a silicon-on-insulator (SOI) complementary metal-oxide-semiconductor (CMOS) process.

FIG. 12 is a schematic of an on-chip amplifier circuit according to various aspects.

FIGS. 13(a)-13(d) show exemplary wafer cross-sections during fabrication of a silicon-beam nanoresonator.

FIGS. 14(a)-14(d) show exemplary wafer cross-sections during fabrication of a metal-beam nanoresonator.

FIGS. 15(a)-15(f) show exemplary wafer cross-sections during fabrication of a polysilicon-beam nanoresonator.

The attached drawings are for purposes of illustration and are not necessarily to scale.

### DETAILED DESCRIPTION

For the purposes of promoting an understanding of the principles of the present disclosure, reference will now be made to the embodiments illustrated in the drawings, and specific language will be used to describe the same. It will nevertheless be understood that no limitation of the scope of this disclosure is thereby intended.

The present disclosure provides a method for design, development, and characterization of electrostatically-transduced nanoelectromechanical resonators using a top-down microfabrication technique, using a silicon-on-insulator (SOI) process flow. SOI-complementary metal oxide semiconductor (CMOS) technology is widely employed in the development of low-power digital microprocessors, such as those used in mobile computing and communication platforms. The selective nature of silicon/silicon dioxide (Si/SiO₂) etching which enables the fabrication of these devices also allows for the development, implementation, and on-chip integration of SOI-NEMS. These dual-gate silicon devices, are reproducible and reliable, have been fabricated with near 100% yield (excluding the outer perimeter of the chip), and can be easily integrated with SOI-CMOS transistors, enabling the development of fully integrated CMOS-NEMS with highly-tunable in-plane and out-of-plane, nonlinear frequency response characteristics.

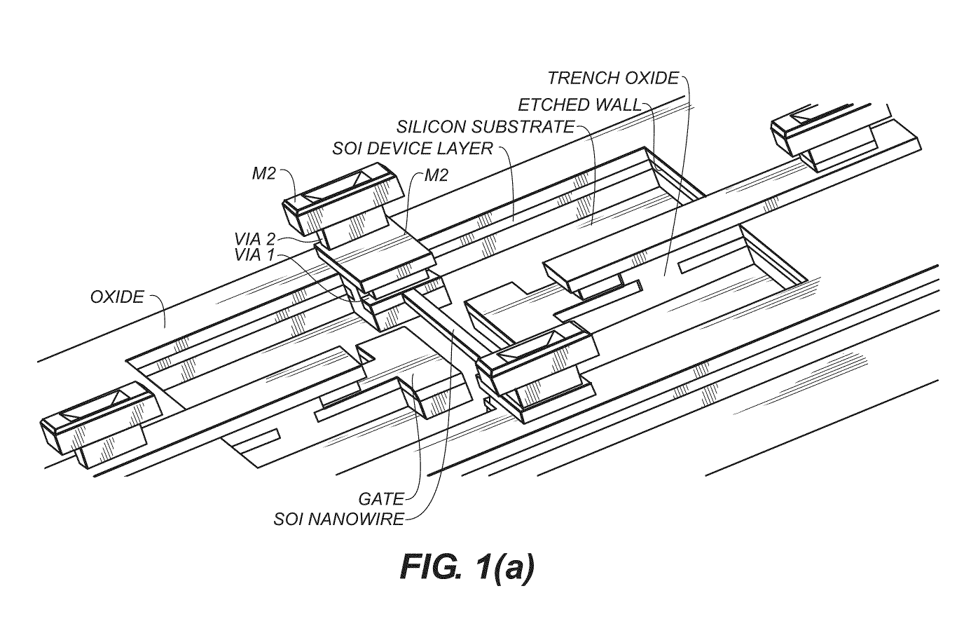

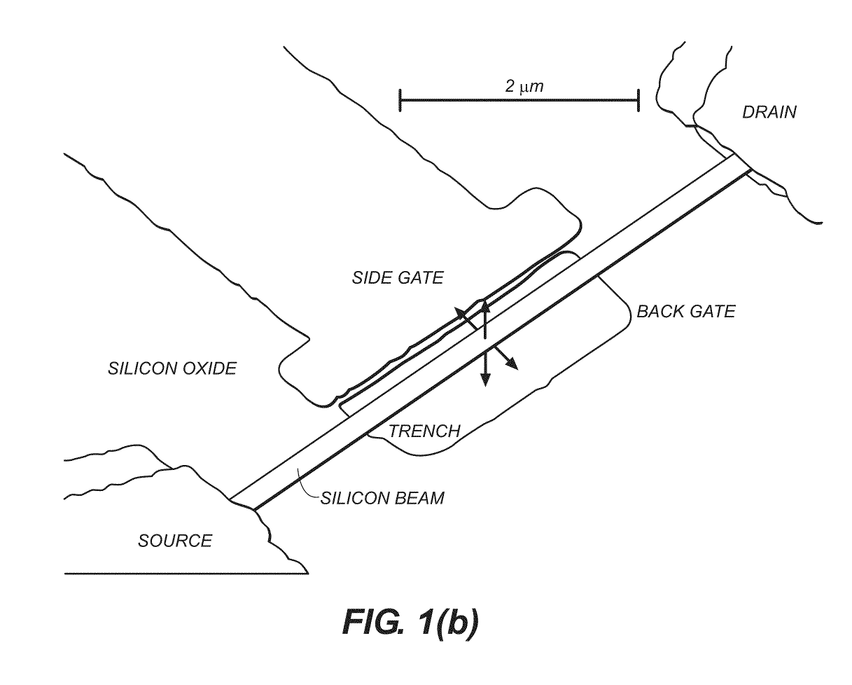

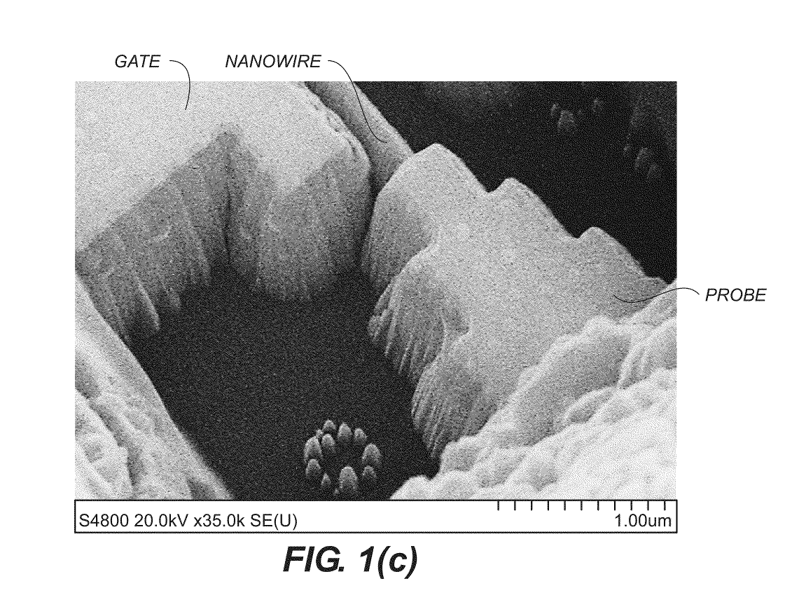

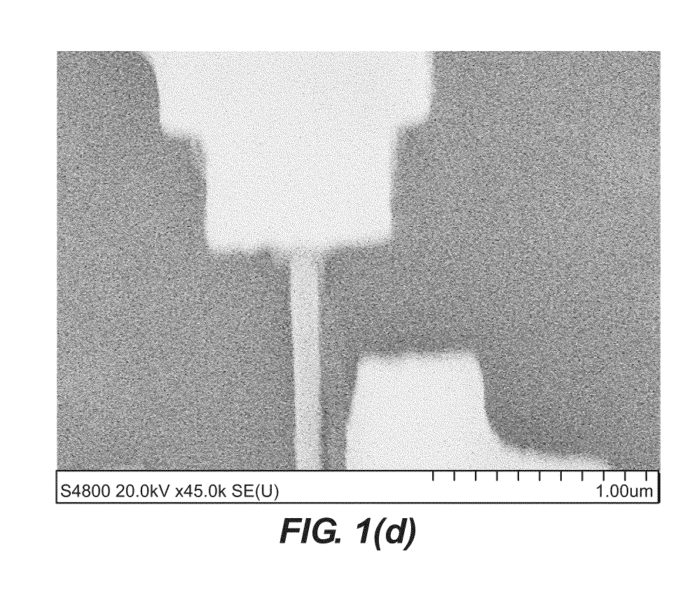

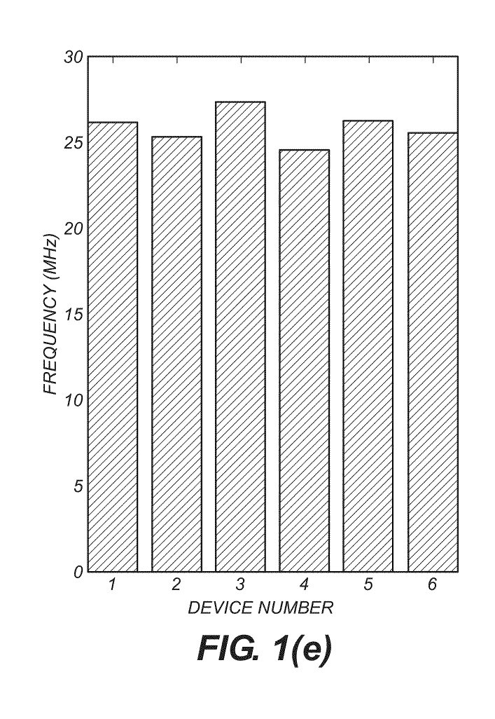

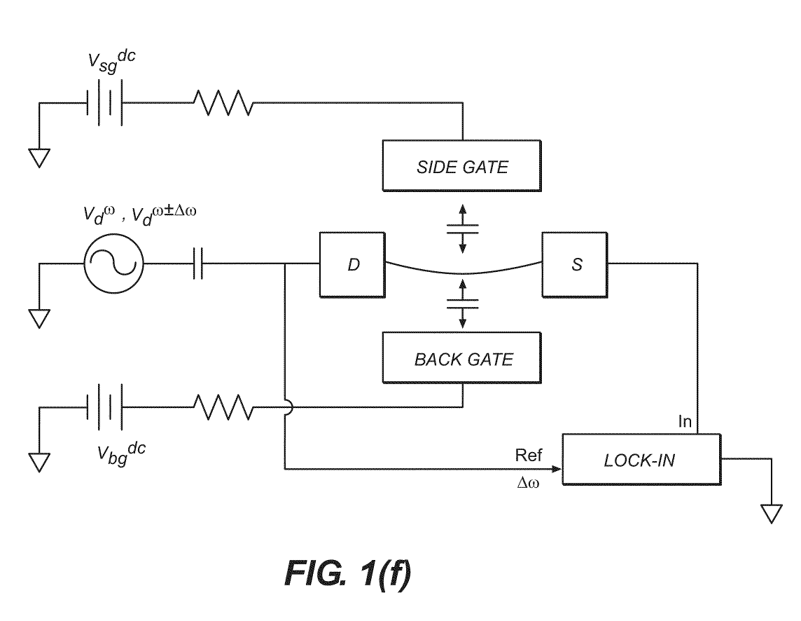

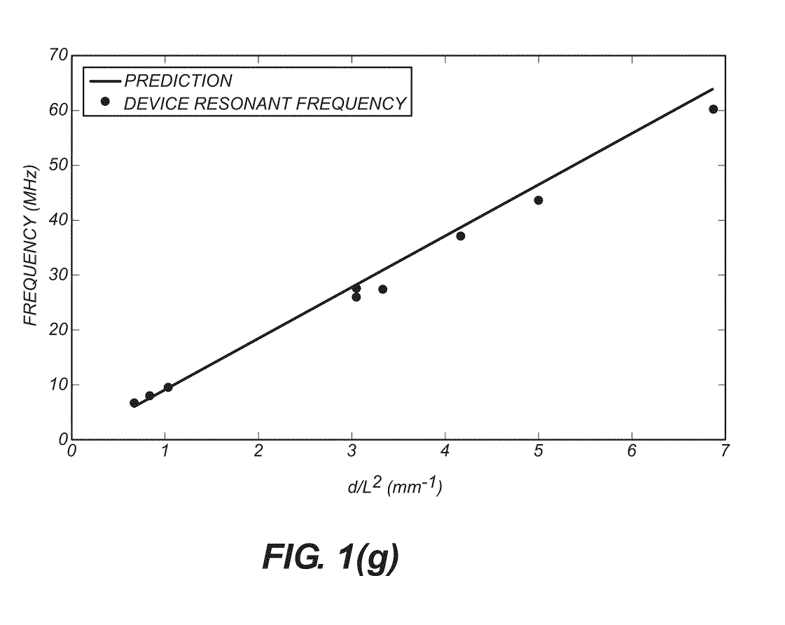

A representative SOI-NEMS device is depicted in FIGS. 1(a)-1(b). The nanoresonator features a near-rectangular cross-section, measuring approximately 110 nm high and 120 nm wide, and is suspended approximately 144 nm above the bottom gate. Phosphorus implantation is used to enhance the conductance of the Si nanoresonators and reduce their contact resistance —key factors in reducing the thermoelectric noise floor of SOI-NEMS. The dual-gate nature of this system allows in-plane and out-of-plane modes of vibration to be selectively actuated and detected through electrostatic mechanisms, ultimately enabling planar, non-planar, and combination (e.g. whirling) motions.

FIGS. 1(c)-1(d) are scanning electron microscope images of the nanowire, according to the present disclosure.

FIG. 1(e) is a graph of linear resonant frequencies of six nanoresonators, according to the present disclosure, with approximately-identical geometries. The geometries of the six devices were designed to be identical, but are not identical due at least to manufacturing-process variation.

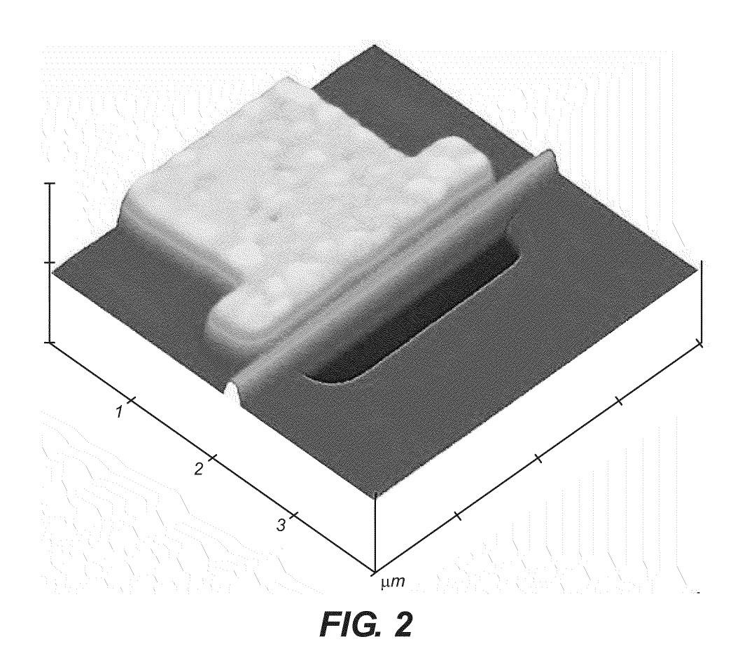

FIG. 1(g) is a graph of measured linear resonant frequencies of nine devices with different geometries and a comparison to theoretical prediction. FIG. 2 shows a typical atomic force microscopic image of a suspended silicon nanowire resonator fabricated with this process.

FIG. 1(f) is a schematic of a measurement setup that can be used to measure the near-resonant response of the dual-gate SOI devices. This arrangement utilizes a high-vacuum chamber (ambient pressure<10⁻⁴ Torr) and an electrostatic measurement technique similar to that previously described in the prior art. Two distinct DC biases are applied on the side gate and back gate, and two AC signals, a pure sinusoid with frequency ω and another with carrier frequency ω and sinusoidal amplitude modulation at Δω, are applied to the drain electrode, facilitating motion and measurement readout. Due to the capacitance change induced by mechanical motion, the two AC signals mix together when their frequencies approaching the natural frequency of the nanoresonator, enabling the vibration of the nanoresonator to be directly measured via the down-mixed current at the intermediate frequency Δω using a lock-in amplifier. As noted in subsequent sections, the detectable mixing current at frequency Δω, which is related to the physical displacement of the device, has two dominant components: a background response induced by the AC voltage applied to the drain and attributable to electrostatic field induced current modulation and a resonant response induced by mechanical motion and attributable to the conductance and piezoresistive changes caused by this motion. Mathematically, this results in a detectable mixing current given by

$${I}^{Δ ω} ( ω ) = \frac{d G}{d {V}_{g}} [ {V}_{DS}^{2} + \frac{{c}_{g} z ( ω )}{{c}_{g}} {V}_{g} {V}_{DS} ] {I}^{Δ ω} ( ω ) = \frac{d G}{d {V}_{g}} [ {V}_{DS}^{2} + \frac{{c}_{g} z ( ω )}{{c}_{g}} {V}_{g} {V}_{DS} ] \qquad ( 1 )$$

where Z(ω) denotes the deflection of the center of the nanoresonator with respect to its equilibrium position, G is the nanoresonator's conductance, C′g and Cg are the differential and absolute capacitances between the gate and device, and V_{g} and V_{ds} are the amplitudes of the gate bias and AC voltage applied to the drain, respectively. Piezoresistive strain can vary at twice of the resonant frequency of the device. The amplitude of the device's response can be less than 10 nm, which corresponds to a capacitance change C′_{g} on the order of 10⁻¹⁹˜10⁻¹⁸ F. As is known in the art, structures undergo thermal vibration. This vibration can be employed even in the absence of an actuating signal V_{ds}. These thermal vibrations can lead to a temperature-dependent response of the nanoresonator.

Using the aforementioned measurement technique a series of devices, with both identical and different dimensions, was characterized. FIG. 1(g) shows the extrapolated linear resonant frequencies of nine devices with different geometries, and a comparison with theoretical prediction. Likewise FIG. 1(e) shows measured linear resonant frequencies of six devices that were fabricated with approximately the same dimensions. The calculated average frequency for these approximately-identical devices is 25.8 MHz, which is close to the predicted resonant frequency of 25.5 MHz. The standard deviation of the measurement is 0.96 MHz.

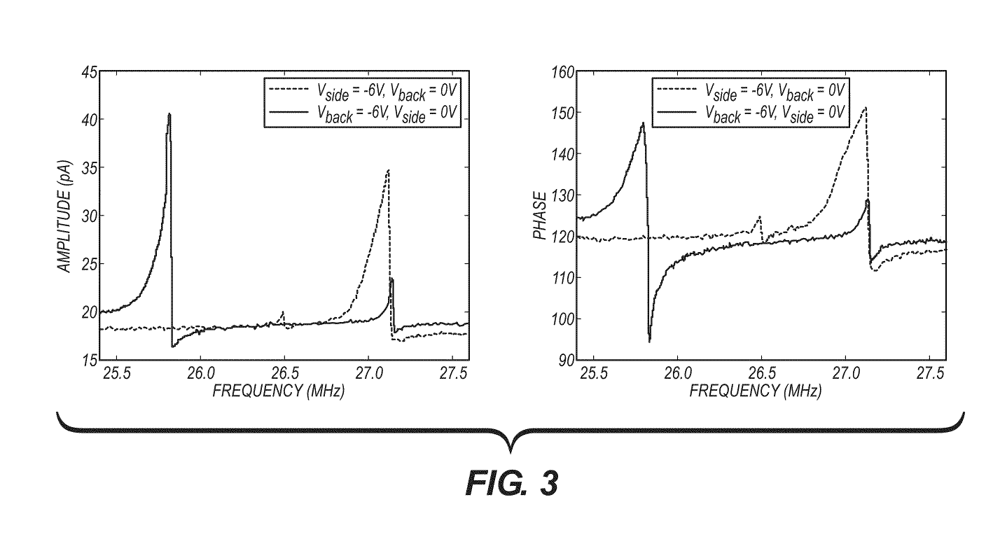

FIG. 3 depicts the frequency response (amplitude of the measured mixing current versus excitation frequency) for a representative dual-gate silicon nanoresonator device actuated with a 15 mVᵣₘₛ source-drain voltage (V_{ds}) under two different bias configurations. The nanoresonator measured approximately 120 nm wide, 110 nm thick, and 6.3 μm long. A source-drain voltage of V_{ds}=15 mVᵣₘₛ was applied to the nanoresonator. Two conditions were tested: (i) V_{side}=−6 V, V_{back}=0 V, shown with a dashed line; and (ii) V_{side}=0 V, V_{back}=−6 V, shown with a solid line. As evident, each response exhibits two distinct resonances. The lower-frequency resonances, which occur in the proximity of the predicted natural frequency of 25.5 MHz, correspond to out-of-plane motions, while the higher-frequency resonances, which occur in the proximity of the predicted natural frequency of 27.7 MHz, correspond to in-plane motions. Due to the dual-gate nature of the structure, these near-orthogonal motions can be selectively utilized, or used in conjunction with one another, in the course of near-resonant device operation. Note that there is a measurable degree of coupling between these motions, largely due to the fringing electric fields generated by the two distinct gates. Also of note from FIG. 3, is the non-Lorentzian shape of the near-resonant response. This is indicative of the fact that the device is operating in a nonlinear frequency response regime, despite the comparatively-small source-drain excitation voltage. While the quality factor (Q) associated with resonance is ill-defined for nonlinear systems, a comparable metric, hereafter referred to as effective quality factor (Q_{eff}), can be estimated from this frequency response using the ratio of center frequency to full width at half maximum (FWHM) definition. Note that Q_{eff} is approximately 3,000 for this device.

FIG. 3 also highlights the tunable nature of the dual-gate devices described herein, a topic discussed at length in the following section. Of particular note is the fact that the resonance frequencies, corresponding to in-plane and out-of-plane motions, shift under different bias conditions. These shifts are attributable to the fact that two distinct tuning mechanisms impact the response of doubly-clamped, electrostatically-transduced nanoresonators: a nonlinear stiffening (hardening) effect, which arises in the presence of large elastic deformations, and a linear and nonlinear capacitive (softening) effect, which is inherent to the variable-gap nature of the electrostatic actuation force. When a DC bias voltage is applied on a gate and a potential difference is created, the resulting electrostatic force attracts the nanoresonator towards the gate, inducing tension in the resonator, a static deflection, and, generally, an increase in the nonlinear resonant frequency (e.g., defined as the frequency of maximum amplitude, or, analogously, the upper bifurcation (jump) frequency). If the DC bias voltage is applied such that the resulting electrostatic force is predominantly in the same direction as the nanoresonator's motion, the bias also provides a capacitive softening effect, which typically reduces the resonant frequency. In the excitation scenarios depicted in FIG. 3, a hardening effect produced by the side gate shifts the out-of-plane resonances to higher frequencies, as seen by benchmarking the lower-frequency resonance as depicted by the various curves shown in FIG. 3. Likewise, a capacitive softening effect produced by the back gate shifts the in-plane resonances to lower frequencies, as seen by benchmarking the higher-frequency resonances as depicted by the various curves shown in FIG. 3.

The ability to finely control the linear and nonlinear frequency response characteristics of nanoresonators is an important aspect to their implementation in practical applications, including sensing and signal processing, and for mitigating the effects of process-induced device variations in these settings. The dual-gate nanoresonator structure detailed herein represents a highly-tunable device platform as it facilitates planar, non-planar, and combined (e.g. whirling) near-resonant motions, which can be tuned bi-directionally.

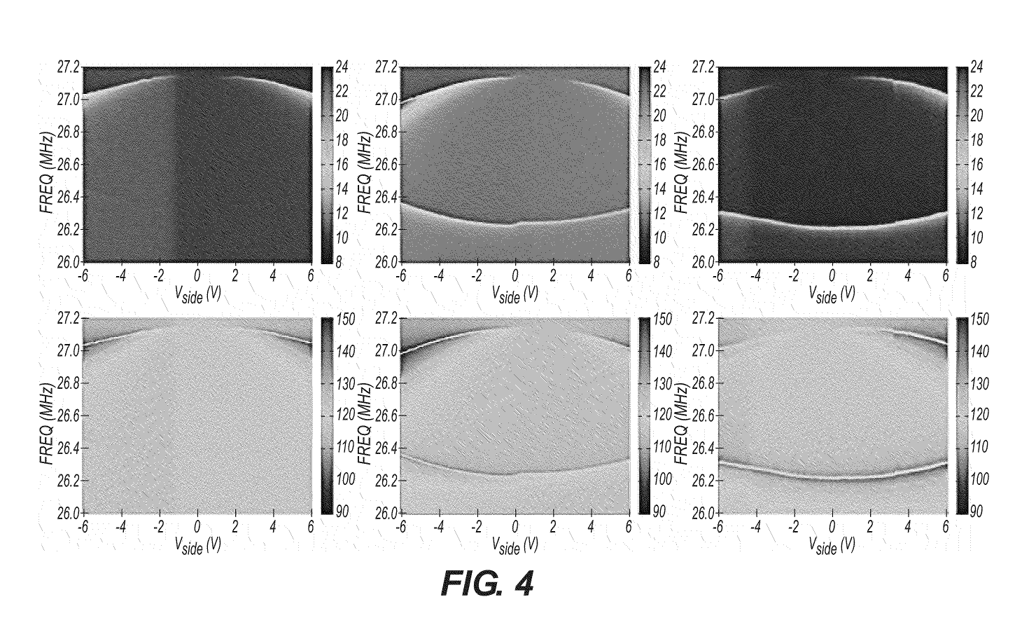

FIG. 4 depicts a representative near-resonant response of a measured nanoresonator at different side-gate biases when the back-gate bias is fixed, as acquired by incrementing the side-gate bias. The amplitude of the AC source-drain voltage excitation is 15 mVᵣₘₛ, and the side-gate bias is changed from −6 V to 6 V in 0.1 V steps.

The upper panels specifically illustrate the magnitude of the detected mixing current (I_{ds}), as a function of both the excitation frequency (ω) and the side-gate bias voltage, (V_{side}) for three distinct back-gate biases (V_{back}) of 0, 3, and −3 V, respectively. The lower panes illustrate the phase of the detected mixing current for V_{back}=0, 3, −3V. Note that a 15 mVᵣₘₛ source-drain voltage was selected for actuation purposes here, as it is just strong enough to drive the near-resonant response above the noise floor (as set by thermomechanical effects and the employed measurement system). As evident, for each back-gate bias, two distinct resonant responses are observable: a comparatively high-frequency response corresponding to an in-plane mode of vibration, and a comparatively low-frequency response corresponding to out-of-plane motion. The difference between the frequencies of these responses can indicate that the beam has a non-square cross-section. Also of note is that for each bias configuration the background response is virtually independent of the DC biases applied on both the back and side gates. This allows the background amplitude to be extracted from experimental measurements, which, in turn, allows for direct comparisons of the near-resonant response.

When V_{back}=0 V, there is no detectable out-of-plane resonance above the noise floor. However, in-plane motions are easily observed. Of note is the fact that the resonance frequency decreases with increasing side-gate bias—a phenomenon consistent with the previously-described capacitive softening mechanism. The lower left panel of FIG. 4 highlights the corresponding phase detected as a function of driving frequency and side-gate bias. Similar frequency tuning effects can be observed. Notably, both the frequency response and the amplitude of the mixing current are asymmetric with respect to the unbiased state, most likely due to residual stress within the nanoresonator.

When V_{back}=3 V, both planar and non-planar motions are detectable. As in the 0V case, the resonance frequency associated with in-plane motion decreases with increasing side-gate bias. In contrast, the peak frequency associated with out-of-plane motions increases with increasing side-gate bias—a phenomenon consistent with the previously-defined stiffening mechanism. The lower center panel of FIG. 4 depicts the corresponding phase change. As previously noted, the amplitude of the measured current is asymmetric with respect to the unbiased state, most likely due to residual stress within the nanoresonator or the asymmetric nature of total electric field. Similar phenomena are observed when V_{back}=−3 V.

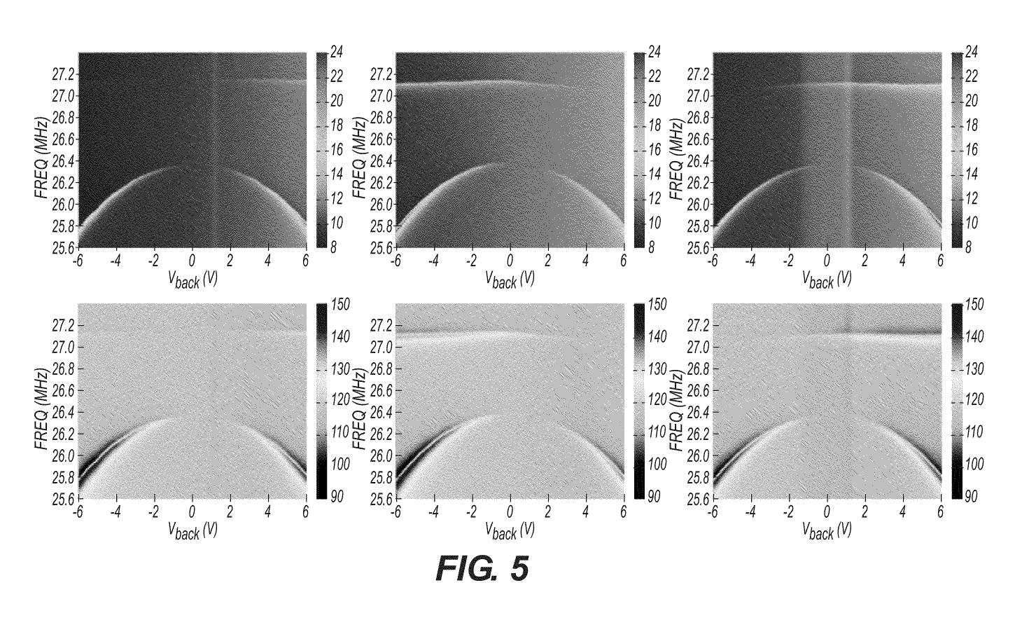

FIG. 5 highlights the resonant response measured from a representative nanoresonator by fixing the side-gate bias and incrementing the back-gate bias. In FIG. 5, the amplitude of the AC source-drain voltage excitation is 15 mVᵣₘₛ, the back-gate bias is changed from −6 V to 6 V in 0.1 V steps, the upper panels highlight the magnitude of the detected mixing current as a function of both the excitation frequency (co) and the back-gate bias voltage (V_{back}) for side-gate bias voltages (V_{side}) of 0, 3, and −3 V, respectively, while the lower panels highlight the corresponding phase for V_{side}=0, 3, −3V. In general, the results recovered through this experimental analysis, mirror those described in FIG. 4, which were recovered by incrementing the side-gate bias. However, one noticeable difference exists—capacitive softening mechanisms appear to dominate in all tuning scenarios.

With the dual gate structure, the peak frequency of the nanoresonators can be tuned either upward or downward. This is due to the combination of interplay between mechanical hardening effects and capacitive softening effects. Note that residual tension and electrostatic fringing fields lead to the asymmetric shape of the frequency response, with respect to the gate bias, recovered from the detected mixing current.

Given the hysteretic nature of the nonlinear response of nanoresonators, a series of frequency sweeps were also initiated to characterize the devices' bifurcation structure and demonstrate how this structure can be tuned by varying the voltage biases applied to the back and side gates. This capability is essential to development of small-scale resonators which actively exploit nonlinear effects in applications such as resonant mass sensing and signal processing, as previously demonstrated at the microscale.

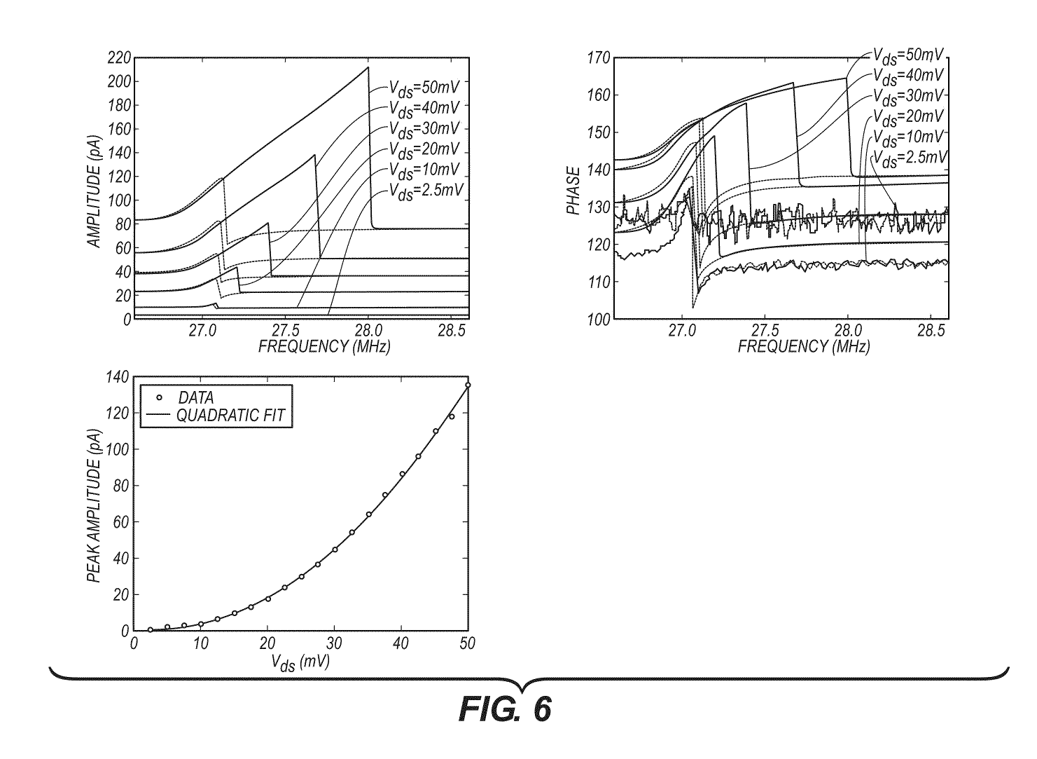

FIG. 6 highlights the measured near-resonant response associated with the planar vibrations of a representative dual-gate resonator as recovered by incrementing the applied source-drain voltage (V_{ds}) and sweeping the excitation frequency up and down. Note that the gate biases are fixed such that V_{back}=0 V and V_{side}=5 V to ensure that the back-gate bias does not affect the in-plane motion. In FIG. 6, the upper-left panel highlights the corresponding mixing current versus frequency trajectories at different source-drain excitation amplitudes by sweeping the excitation frequency up and down, respectively (the solid lines correspond to frequency sweeping up and the dash lines correspond to frequency sweeping down), the upper-right panel highlights the corresponding phase versus frequency trajectories at different source-drain excitation amplitudes, and the right panel shows the extracted peak amplitude as a function of the source-drain voltage amplitude (subtracting the background amplitude) as obtained by sweeping the frequency. As evident, the system exhibits a Duffing-like response characteristic, bistability over a finite frequency bandwidth, and hysteresis with respect to the direction of the frequency sweep. Bistability here refers to the fact that there are coexistent stable steady-state solutions over finite bandwidths of excitation frequency. Which state is obtained is a function of the excitation, initial conditions and noise. The upper-left and upper-right panels highlight the detected mixing current and corresponding phase change as V_{ds} is increased. Note that V_{ds}=2.5 mV approximates the thermomechanical/thermoelectric noise floor of the measured system. Under such low drain source voltage, the peak resonance response (proportional to V_{ds} as seen from Eq. 1) and the background electrostatic field current modulation (proportional to V_{ds}²) become comparable to the noise floor of the system. Contributing noise sources to the noise floor in the system include Johnson noise from both the resonator and the lock-in amplifier, 1/f noise, thermomechanical noise, adsorption—desorption noise and defect motion noise. This figure reveals that with increasing V_{ds} the bandwidth and center frequency of the hysteretic region increase in a consistent manner—a mechanism that can be advantageously leveraged in practical application. The lower-left panel depicts the extracted peak amplitude as a function of the source-drain voltage amplitude (subtracting the background amplitude) as obtained by sweeping the frequency.

Similar nonlinear behavior to that detailed in FIG. 6 is observed for the non-planar vibrations as well. In this experimental analysis, the gate biases are fixed such that V_{back}=5 V and V_{side}=0 V, and the amplitude of the AC source-drain voltage is incremented.

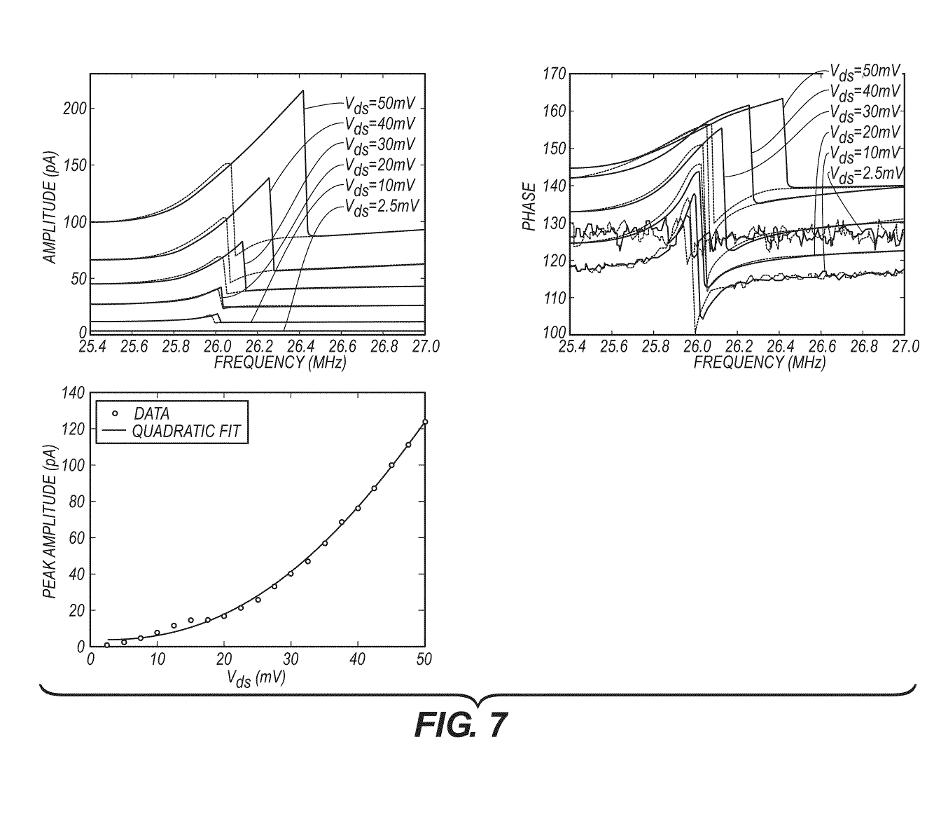

FIG. 7 shows the measured non-planar response when V_{ds} is increased. In FIG. 7, the upper-left panel highlights the corresponding mixing current versus frequency trajectories at different source-drain excitation amplitudes by sweeping the excitation frequency up and down, respectively (the solid lines correspond to frequency sweeping up and the dash lines correspond to frequency sweeping down), the upper-right panel highlights the corresponding phase change versus frequency trajectories at different source-drain excitation amplitudes, and the lower-left panel shows the extracted peak amplitude as a function of the source-drain voltage amplitude (subtracting the background amplitude) as obtained by sweeping the frequency. The measured response characteristics are qualitatively similar to those shown in FIG. 6.

To further characterize the nonlinear frequency response structure, the device's back-gate bias was fixed at zero and the side-gate bias was incremented from −5 V to 5 V, with the upper and lower bifurcation (jump) frequencies being recorded at each step.

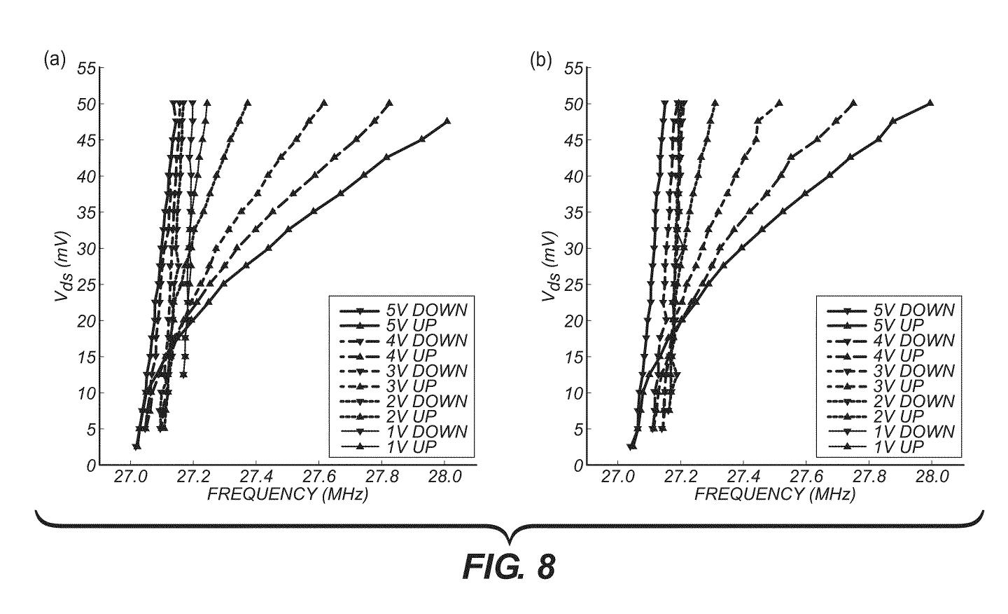

FIG. 8 shows the results of this experimental analysis when (left) negative and (right) positive DC biases are applied. The diagrams were constructed by experimentally locating upper and lower jump bifurcations in a nanoresonator similar to that shown in FIG. 1(b), highlighting the nonlinear characteristics associated with planar vibration, the panels highlight the system's tunability with (left) negative side-gate biases and (right) positive side-gate biases, respectively (it should be noted that as the side-gate bias (V_{side}) is increased, the apex of each bifurcation wedge shifts to lower frequencies, due to a capacitive softening effect, while simultaneously, the top of each wedge shifts towards higher frequencies, indicating an increased frequency bandwidth associated with hysteresis at higher AC source-drain voltages (V_{ds})). As evident, for small AC source-drain voltages no hysteresis is observed. However, at modest source-drain voltages, hysteresis (nonlinearity) occurs. As the side-gate bias is increased, the apex of each bifurcation wedge shifts to lower frequencies, due to a capacitive softening effect. Simultaneously, the top of each wedge shifts towards higher frequencies, indicating an increased frequency bandwidth associated with hysteresis at higher AC source-drain voltages. The onset of nonlinearity can be characterized by a critical voltage excitation amplitude, which is defined to be the point at which the frequency response structure features an infinite slope. Using this criteria in the context of FIG. 8 allows the critical amplitude to be defined as the source drain voltage at which the frequency trajectories recovered via up-sweep and down-sweep start to deviate from each other for a given gate bias. Examining the right panel, as an example, allows one to conclude that the critical excitation amplitude is approximately V_{ds}=5 mV for V_{side}=5 V for the devices considered here.

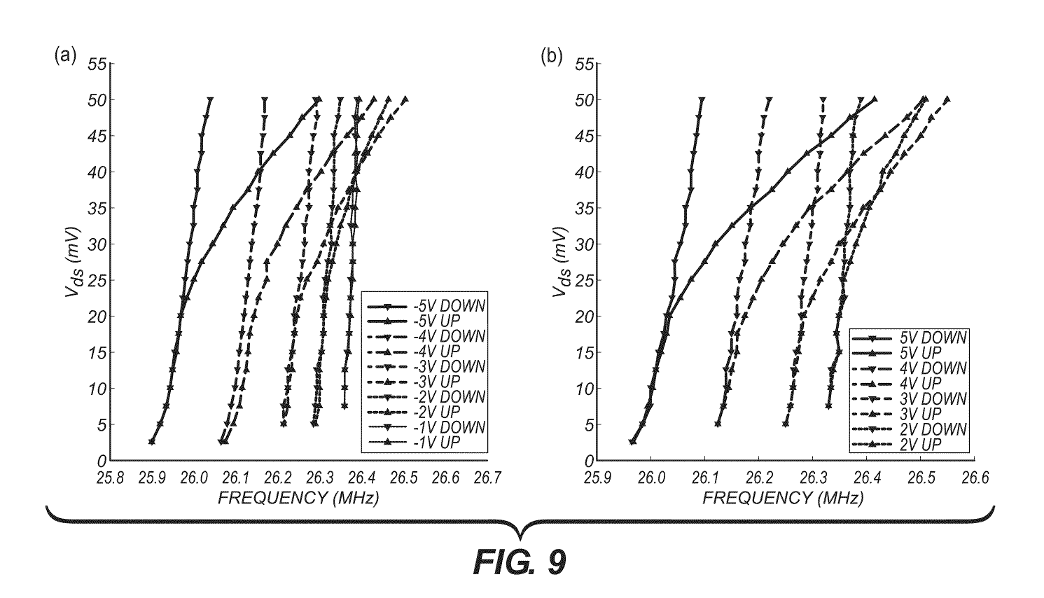

Similarly, FIG. 9 highlights the bifurcation structure associated with out-of-plane device motions when the side-gate bias is fixed at zero and the back-gate bias is incremented from −5 V to 5 V. FIG. 9 was constructed by experimentally locating upper and lower jump bifurcations in a nanoresonator similar to that shown in FIG. 1(b), highlighting the nonlinear characteristics associated with out-of-plane vibration, the insets highlight the system's tunability with (a) negative side-gate biases and (b) positive side-gate biases, respectively (it should be noted that as the side-gate bias (V_{side}) is increased, the apex of each bifurcation wedge shifts to lower frequencies, due to a capacitive softening effect, while simultaneously, the top of each wedge shifts towards higher frequencies, indicating an increased frequency bandwidth associated with hysteresis at higher AC source-drain voltages (V_{ds})). Again, the qualitative characteristics observed for planar motions appear to remain in the case of non-planar motion.

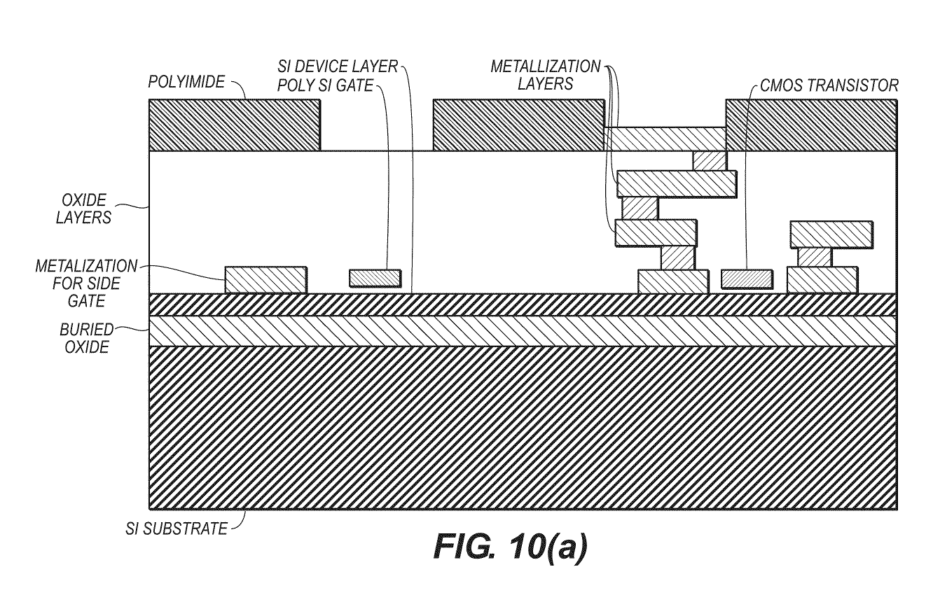

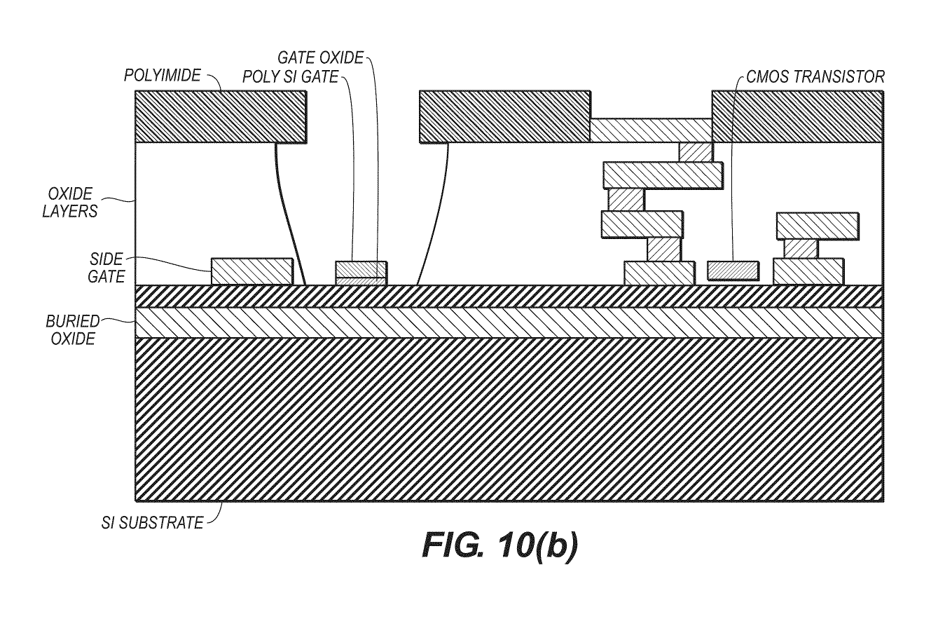

To fabricate nanoresonators according to various aspects described herein, SOI wafers with 110 nm device layer and 144 nm buried oxide layer can be used. Exemplary wafers are slightly doped with boron (p=14-20 Ω-cm), e.g., in the device layer. Prior to device fabrication, the SOI wafers are implanted with phosphorous. An impurity dose of 1×10¹³ cm⁻² and an implantation energy of 40 KeV are employed to ensure that the peak concentration (with an estimated doping density of 10¹⁸/cm³) appears in the middle of the device layer. After ion implantation, the wafers are annealed at 1050° C. in a nitrogen ambient for 60 sec using a rapid thermal annealing (RTA) furnace. The RTA anneal allows the dopant, namely phosphorous, to diffuse into the substitutional lattice sites where they are electrically active. As can be seen in each of FIGS. 10(a)-10(d), the wafer includes, from bottom up, a silicon substrate, a buried oxide layer, and a silicon device layer.

Single-crystalline silicon nanoresonators can be formed on various substrates, e.g., SOI and SOI CMOS. In an exemplary SOI fabrication process that does not require typical CMOS process steps, the silicon nanoresonators are fabricated following the dopant activation. First, a layer of hydrogen silsesquioxane (HSQ) is spin-coated on top of the device layer. The silicon nanoresonators are then patterned with e-beam lithography using HSQ as a high-resolution, negative tone inorganic electron beam resist. After development, the exposed HSQ remains on the wafer, which is then introduced into a reactive ion process. After plasma etching, the wafer is dipped in buffered oxide etchant (BOE) for 30 sec to remove the HSQ. Another e-beam lithography process is then performed to define the source, drain and side gate electrodes. This process step is followed by metal deposition and a lift-off process. The thick metal contacts are realized with 30 nm chrome and 200 nm gold in order to achieve good step coverage of the silicon nanoresonators. It should be appreciated that a small window is patterned between source and drain with another e-beam lithography process and the SiO₂ beneath the resonators is etched in BOE. Finally, the suspended resonators are released through the use of a critical point drying (CPD) process.

In various aspects using SOI-CMOS substrates, conventional deposition and lithographic patterning processes such as those used for CMOS fabrication are used to define features on the SOI wafer. In these examples, above the silicon device layer of an SOI wafer are formed various metallization and polysilicon layers, e.g., as shown in FIG. 10(a). FIGS. 10(a)-10(d) show post-processing steps for fabricating a silicon nanoresonator using a SOI-CMOS wafer. The SOI-CMOS wafer is designed to have features illustrated in FIGS. 10(a)-10(d). This can be done using conventional wafer-design and integrated-circuit-design techniques and tools, e.g., ORCAD or CADENCE VIRTUOSO.

FIG. 10(a) shows a wafer having patterned features, including a poly-Si gate surrounded by oxide over the area where the nanoresonator beam is to be formed. In various aspects, the wafer includes a SOI substrate and metallization; this figure shows the wafer after CMOS foundry fabrication and before post processing. The polyimide openings shown have been designed to permit exposing plasma to the silicon dioxide above the nano resonator, while protecting the rest of the chip. The polysilicon gate shown has been designed to serve as mask in the post processing. Instead of polysilicon, a Metal layer (e.g. M1) can be used as a mask (this configuration is not shown).

FIG. 10(b) shows the oxide etched away in an area exposed by the polyimide. The result is that the silicon device layer of the SOI wafer (above the buried oxide) is exposed under the gap in the polyimide, except where the poly-Si gate is located. In various aspects, FIG. 10(b) shows the results of plasma dry etching of the oxide layers (e.g., SiO₂) above the silicon device layer. The polyimide layer has served as mask for the plasma to protect the CMOS circuitry and other features of the wafer. In various aspects, the SiO₂ stack is designed not to include any metal, or is designed not to include any metal or polysilicon. In an example, the SiO₂ layer does not include metal auto-fillers. Metal auto fillers are embedded metal solids, e.g., cubes, made from the metallization of the CMOS chip. In some wafer designs, auto fillers are automatically added to the oxide regions, keeping the density of metal below a desired value. In various aspects, the SiO₂ is free of any auto fillers.

FIG. 10(c) shows the poly-Si gate and the monocrystalline Si device layer etched away, leaving a layer of gate oxide over an island of the Si device layer. In various aspects, FIG. 10(c) shows the results of a plasma dry etching step for single crystalline silicon. This step defines the nano resonator on the silicon device layer of the SOI substrate. The polysilicon gate has served as mask, in this example, and been etched away simultaneously with the etching of the device layer to define the beam. In aspects using a metal layer as a mask instead of polysilicon, the metal can be etched away after defining the beam, e.g., using a wet etching technique.

FIG. 10(d) shows the buried oxide layer etched away, forming the trench (FIG. 1a, 1b) and freeing the Si beam to vibrate. In various aspects, FIG. 10(d) shows the results of a plasma dry etching step for SiO₂ below the nano resonator (in the buried oxide layer), followed by a SiO₂ isotropic wet etching step to suspend the beam in the air. This release step can be followed by a Critical Point Drying (CPD) step to reduce surface tension that might otherwise tend to stick the beam to, e.g., the sidewall of the side gate.

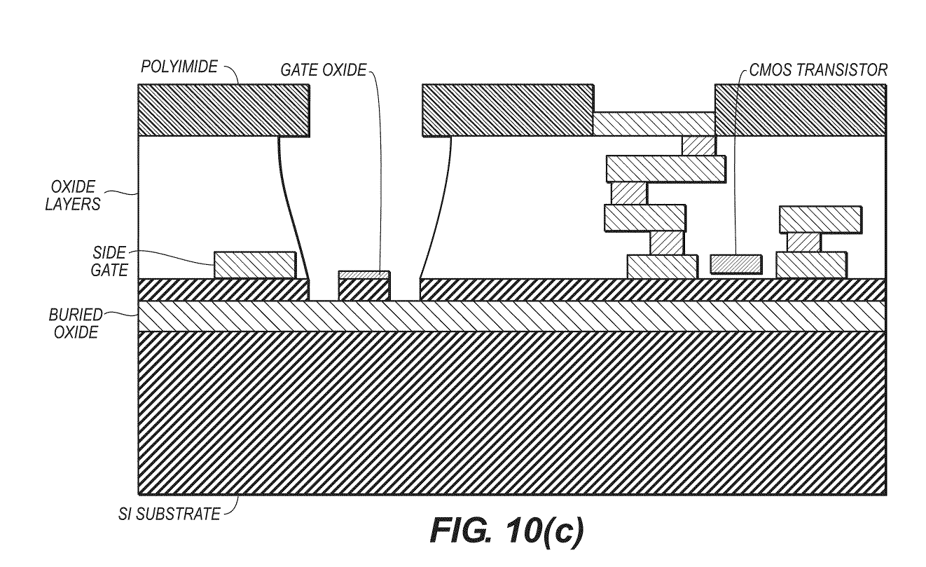

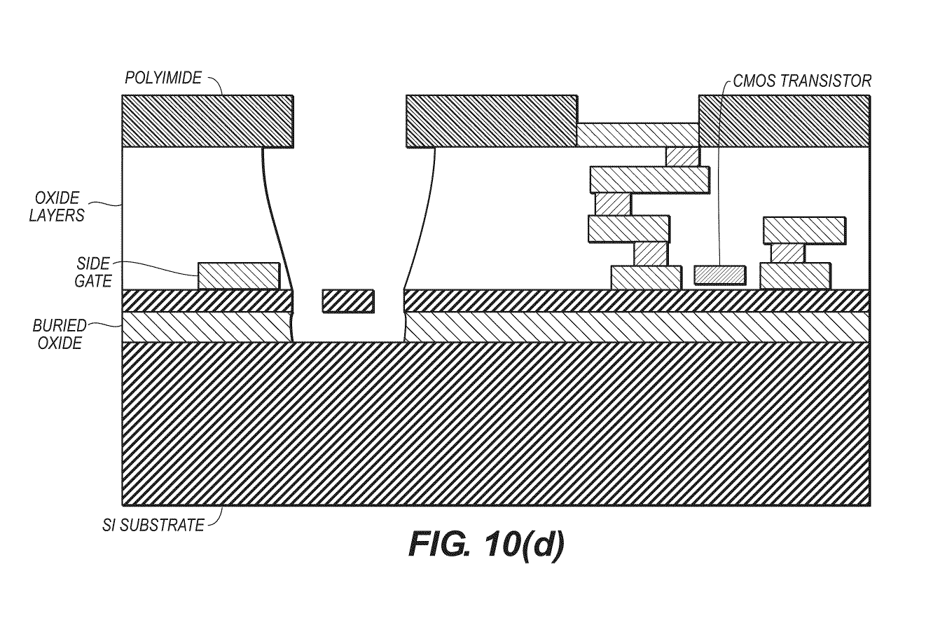

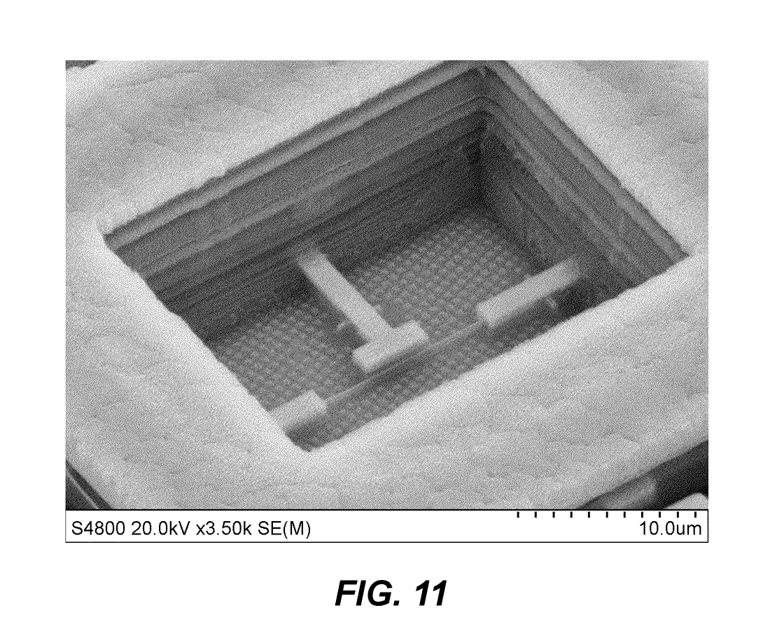

FIG. 11 is a representation of a micrograph of a portion of a nanoresonator fabricated using a silicon-on-insulator (SOI) complementary metal-oxide-semiconductor (CMOS) process.

The integration of NEMS/MEMS and Complementary Metal Oxide Semiconductor (CMOS) on one chip offers many advantages over the traditional approach of connecting MEMS and CMOS-like chips through wire bonding and wafer-to-wafer bonding. The first advantage of NEMS/MEMS to CMOS integration is the lower coupled noise which leads to higher device sensitivity. Undesired coupling can dominate the performance of the device when device dimensions are decreased to nano-scale dimensions where detected signals are increasingly weaker. NEMS-CMOS integration enhances measurement bandwidth as well. The bandwidth of motion detection is limited by the parasitic capacitance in the detection circuit. If the output impedance of the NEMS device is Re, and the detection circuit parasitic capacitance is Cp, the cut-off frequency of the system can roughly be calculated as 1/(ReCp), which determines the measurement bandwidth. By utilizing an on-chip amplifier, the NEMS parasitic capacitance can be significantly lowered leading to very high measurement bandwidths. Light weights, small form factors and lower costs are additional advantages of NEMS/CMOS integration. In various aspects, one or more of the components shown in FIG. 1(f), e.g., the voltage sources and the lock-in amplifier, is implemented on CMOS integrated with a MEMS/NEMS nanoresonator.

In various aspects, single crystal (monocrystalline) silicon beams are used as the resonating structures of an integrated NEMS/CMOS technology. The technique used for fabricating the NEMS devices does not require any NEMS-specific lithography step.

In the nano-scale regime, the roles of surfaces and defects become more dominant and the importance of molecular interactions and quantum effects are magnified. Single-crystalline silicon is a homogenous crystalline structure which has no grain boundaries, leading to fewer defects in the beam structure. In various aspects, monocrystalline silicon beams advantageously provide reduced energy dissipation in the beam and enhanced quality factor and thus sensitivity of miniaturized resonant sensors. Various monocrystalline Si beams can also provide improved beam stiffness, improving the aging performance of the beam and the expanding the frequency range of operation upward. Various monocrystalline Si beams can also provide reduced diffusional creep and increased thermal conductivity. Various metal beams fabricated as described herein can advantageously provide increased beam effective mass and decreased energy loss due to higher electrical conductivity.

Referring back to FIG. 1(a), an exemplary NEMS nanoresonator is based on the resonance of a doubly clamped Si beam with source and drain contacts on each side and a close-by gate electrode. A high quality factor (Q) in the order of 10³ can be achieved. The nonlinear property of the vibrating beam commonly referred to parametric excitation can advantageously be used. The nonlinear oscillation of the beam can be amplified by synchronized actuation of the beam, which results in higher amplitudes of output signal. Higher quality factors can be achieved using this technique, enabling highly tunable characteristics and improved sensitivity.

FIG. 1(f) shows components monolithically fabricated in a single CMOS chip. The SOI nanowire is a suspended doubly clamped Si beam, and can be fabricated, e.g., using a top-down process. The M2 (Metal 2) layers include contacts for source and drain, at the ends of the nanowire, and gates on either side. A back gate, FIG. 1(b), can also be fabricated. The monolithic NEMS/CMOS system can also include amplifier circuit; interconnections between the NEMS device and the amplifier; and top pads (not shown).

In various aspects, excitation and detection of the beam are done electrostatically. The beam is electrostatically excited by applying an AC signal to the Si beam. The electrostatic force F can be determined as F=0.5 C′ V² where C′ is the spatial derivative of the beam-gate capacitance and V is the potential difference between the gate and the beam. By applying a DC voltage to the gate electrode and reading out the induced current in the beam, the capacitive variations of the oscillating beam can be monitored.

A standard 45 nm CMOS SOI technology can be used to fully integrate the beam with CMOS devices. In various aspects, a suspended beam is formed on the device layer of a Silicon on Insulator (SOI) substrate, and the isolation layer (Buried Oxide or BOX) is used as a sacrificial layer to release the beam. The resonance frequency of the beam is set by beam dimensions and properties.

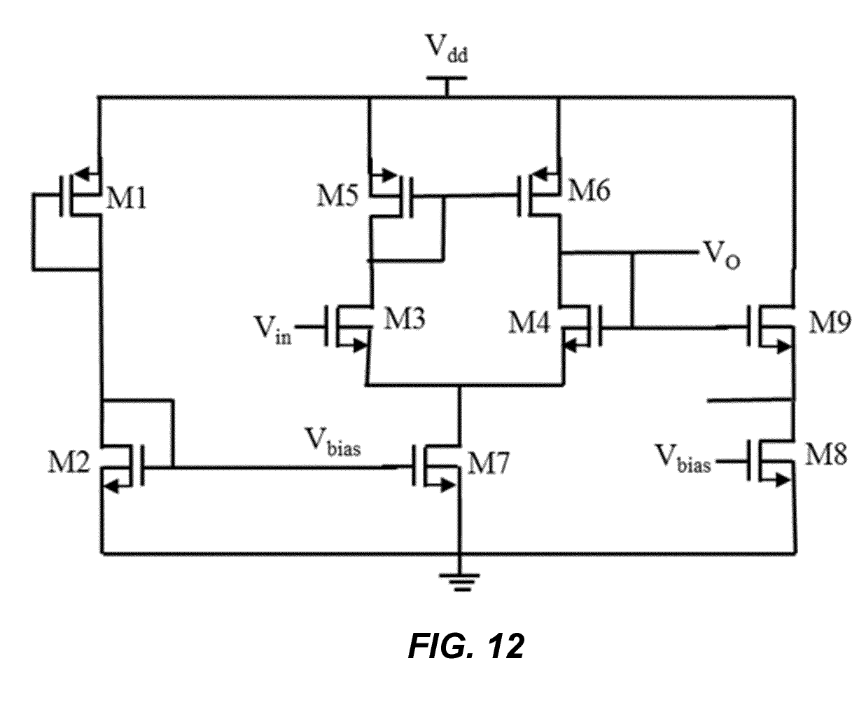

FIG. 12 is a schematic of an on-chip amplifier circuit that can be used to amplify the signal of the NEMS device. The amplifier includes a biasing stage, an input stage, and an output stage. The input stage is fed through transistors M1 and M2 and uses a threshold independent level-shifter topology, which is formed in a source-follower assembly (transistors M3 to M7). An additional source-follower forms the output of the amplifier (M8, M9), which enables loading of capacitances in the circuit test measurements. The amplifier is designed with a high bandwidth, which covers the out of plane resonance frequency range, without requiring mixing down the frequency (although downmixing can be employed).

An exemplary nanoresonator is fabricated using a standard 45 nm SOI CMOS technology. In this example, the CMOS transistors and top metallization are fabricated on an SOI substrate. The minimum poly-silicon gate size is 45 nm. All metallization layers except the top layer are formed with Copper. The very top metal layer commonly used for pads is made of Aluminum. Minimum dimension of the lowest metal layer (M1) is 70 nm in this example, and minimum poly-Silicon width is 40 nm (exemplary). Several physical design rules impose limitations on different aspects of the NEMS resonator design. Beam thickness and width, beam-substrate distance and beam-gate distance are among the parameters which are affected by these standard rules. For example, the minimum width of the first metal layer (70 nm) can determine the minimum width of the silicon nanoresonator, because M1 serves as a masking layer to etch the Si beam later on in post processing steps. Beam to substrate gap is fixed and is equal to the thickness of the SOI isolation layer (Box). This layer plays a critical role as a sacrificial layer. Beam length can be designed in accordance to the gap formed by the sacrificial layer. In this example, this gap can set the limitation in the length of the beam since very narrow gap can cause long beams to stick to the side or bottom surfaces during the suspension step.

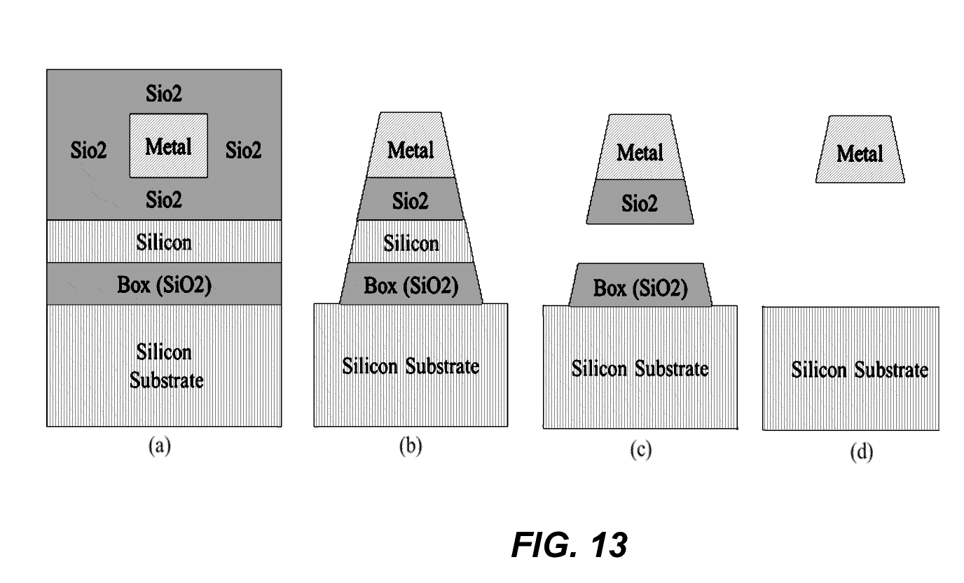

FIGS. 13(a)-13(d) show exemplary wafer cross-sections during fabrication of a silicon-beam nanoresonator. Throughout FIGS. 13-15, “Sio2” and “SiO₂” are used interchangeably. First, the device is designed including openings top passivation and top metal layers above the nanoresonator. These openings expose the NEMS resonator, buried under an oxide stack, to the post-processing procedure. Metal 1 and Metal 2 masks are designed. The design is taped out to CMOS foundry for fabrication, e.g., in 45 nm SOI technology. FIG. 13(a) shows the result.

Anisotropic dry etching is performed to etch the SiO₂—Si stack and define the NEMS resonator. In this step, CMOS circuitry is protected by the top polymer and top metal layers. Metal 2 acts as a mask for source, drain and gate interconnects and Metal 1 masks the plasma to carve out the Si nanoresonator. FIG. 13(b) shows the result.

The metal (e.g., copper) masks are then etched away, using wet etching technique. FIG. 13(c) shows the result.

The silicon beam is then released by etching the sacrificial layer (oxide) using a vapor HF setup. FIG. 13(d) shows the result.

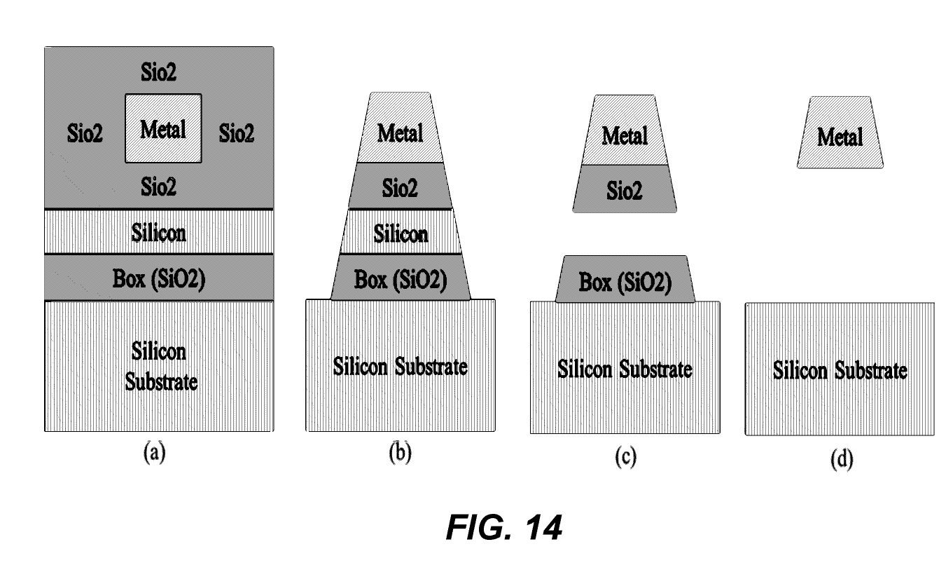

FIGS. 14(a)-14(d) show exemplary wafer cross-sections during fabrication of a metal-beam nanoresonator. A small opening is designed in the CMOS passivation layer and top aluminum layer to expose parts of the chip to the plasma and protect the rest from being etched. After tape-out and CMOS fabrication the wafer is as shown in FIG. 14(a). Anisotropic dry etching is then performed, using Reactive Ion Etching (RIE) technique, to etch down to the silicon substrate. FIG. 14(b) shows the result.

Isotropic dry etching of the silicon body is then performed, using, e.g., a reactive-ion etching (RIE) technique, to etch the silicon device layer as the first sacrificial layer. Higher RIE chamber pressure, higher RF power and lower capacitive power are among parameters that help achieving an isotropic dry etching. FIG. 14(c) shows the result.

SiO₂ isotropic etching using vapor HF is then performed to etch the sacrificial oxide layers, releasing the metal beam. The result is shown in FIG. 14(d).

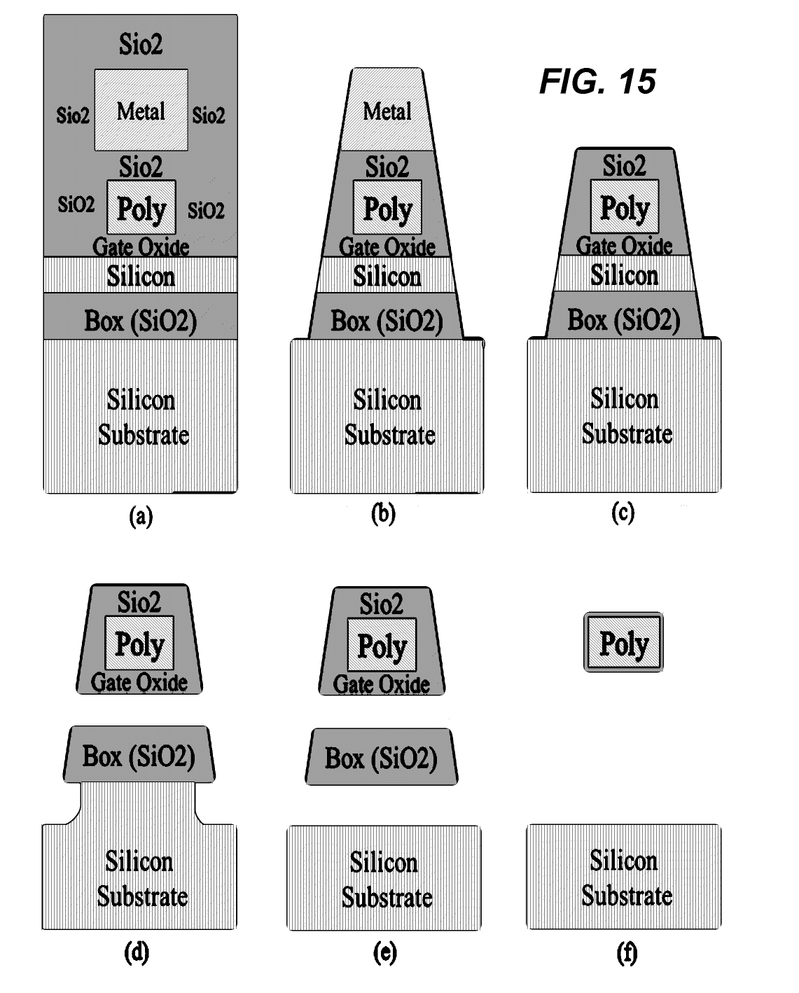

FIGS. 15(a)-15(f) show exemplary wafer cross-sections during fabrication of a polysilicon-beam nanoresonator. After designing of the poly-Silicon beam, layout is sent to CMOS foundry for fabrication. The result is shown in FIG. 15(a). Next, anisotropic dry etching is performed, to carve the Silicon dioxide around the poly-Silicon beam. RIE techniques can be used for this step. Metal 1 serves as a mask for the Poly-Si beam from being attacked by the plasma. FIG. 15(b) shows the result.

Next, the metal (e.g., copper) mask (M1) is etched away using a wet etching technique. FIG. 15(c) shows the result.

Next, isotropic plasma etching is performed to etch the silicon device layer, which is the first sacrificial layer. FIG. 15(d) shows the result.

Plasma etching is continued to partly etch the silicon substrate. This way, a beam-to-substrate gap is extended which reduces the probability of the beam's sticking to the substrate. FIG. 15(e) shows the result.

Isotropic SiO₂ etching is then performed using vapor HF to etch the SiO₂ as the second sacrificial layer. FIG. 15(f) shows the result.

In various aspects, other devices than doubly-clamped nanowires can be formed using techniques and processes described herein. Sensors or actuators having various modes of operation (e.g., electromagnetic, thermal, optical, piezoresistive, and piezoelectric) can be formed. Various geometries of these devices can be formed, e.g., beams, wires, plates, or disks.

The invention is inclusive of combinations of the aspects described herein. References to “a particular aspect” (or “embodiment” or “version”) and the like refer to features that are present in at least one aspect of the invention. Separate references to “an aspect” or “particular aspects” or the like do not necessarily refer to the same aspect or aspects; however, such aspects are not mutually exclusive, unless so indicated or as are readily apparent to one of skill in the art. The use of singular or plural in referring to “method” or “methods” and the like is not limiting. The word “or” is used in this disclosure in a non-exclusive sense, unless otherwise explicitly noted.

The invention has been described in detail with particular reference to certain preferred aspects thereof, but it will be understood that variations, combinations, and modifications can be effected by a person of ordinary skill in the art within the spirit and scope of the invention.

1. A device, comprising:
a) a silicon substrate, an oxide layer disposed over the silicon substrate and including a trench, and a silicon device layer disposed over the oxide layer;
b) at least one complementary metal-oxide-semiconductor (CMOS) transistor;
c) a nanowire substantially suspended over the trench and electrically connected at each end to a respective contact; and
d) two gate electrodes, each spaced apart from the nanowire and operatively arranged to develop a respective capacitance with the nanowire, wherein the two gate electrodes lie along different axes with respect to the nanowire;
e) so that the nanowire can be excited to vibrate in an in-plane mode or an out-of-plane mode by controlling a current through the contacts and a respective bias of each of the two gate electrodes.

2. The device according to claim 1, wherein at least one terminal of the CMOS transistor is electrically connected to one of the contacts.

3. A silicon device, comprising:
a) a silicon substrate;
b) an oxide layer disposed over the silicon substrate, the oxide layer having a trench therein;
c) a silicon device layer disposed over the oxide layer, the silicon device layer including a nanowire disposed at least partly over the trench, wherein substantially no oxide or polysilicon is disposed over the nanowire within a lateral extent of the trench; and
d) a polyimide layer disposed over the silicon device layer, the polyimide layer including an opening substantially arranged over the trench.

4. The silicon device according to claim 3, further including a second oxide layer disposed between the silicon device layer and the polyimide layer, wherein the second oxide layer includes a void substantially arranged over the trench.

5. A system for measurement of a nanoresonator, the system comprising:
a) an AC source in series with the nanoresonator, the AC source adapted to provide an electrical signal to the nanoresonator at a selected first frequency;
b) one or more electrode(s), each arranged adjacent to and spaced apart from the nanoresonator, and a voltage source adapted to apply respective selected voltage(s) to the electrode(s); and
c) a detector adapted to detect a current through the nanoresonator.

6. The system according to claim 5, wherein the nanoresonator is a nanowire comprising silicon.

7. The system according to claim 5, wherein the one or more electrode(s) include two electrodes.

8. The system according to claim 5, wherein a first one of the two electrodes is arranged laterally adjacent to the nanoresonator, and a second one of the two electrodes is arranged vertically adjacent to the nanoresonator.

9. The system according to claim 5, wherein the AC source is further adapted to provide an amplitude-modulated (AM) signal contemporaneously with providing the electrical signal, wherein the AM signal has a carrier at the selected first frequency and is modulated at a selected modulation frequency different from the selected first frequency.

10. The system according to claim 9, wherein the detector includes a lock-in amplifier adapted to detect current at the selected modulation frequency.

11. The system according to claim 5, wherein the nanoresonator and the detector are formed on a single wafer.

12. The system according to claim 11, wherein the wafer is a silicon-on-insulator wafer and the detector includes a complementary metal-oxide-semiconductor (CMOS) transistor.
